(19) United States
(12) Patent Application Publication
(10) Pub. No.: US 2008/0236755 A1
(43) Pub. Date: Oct. 2, 2008

(54) Single-wafer type substrate processing apparatus having a carry-in port provided with first and second placement tables arranged in a line

(75) Inventors: Keisuke Kondoh, Nirasaki-Shi (JP); Shin Osada, Nirasaki-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/076,975

(22) Filed: Mar. 26, 2008

(30) Foreign Application Priority Data
Mar. 30, 2007 (JP) 2007-095399

(51) Int. Cl. H01L 21/306; B05C 13/02; B05C 11/00

(52) U.S. Cl. 156/345.51; 118/500; 118/697; 156/345.24

(57) ABSTRACT

A single-wafer type substrate processing apparatus includes: a plurality of process modules connected to a substrate transfer chamber; a carry-in port having a plurality of first placement tables arranged in a horizontal direction so that a substrate carrier is placed thereon; a second placement table installed on the left or right of an area where the first placement tables are arranged in the horizontal direction so that the substrate carrier is temporarily placed thereon; and a transfer mechanism transferring the substrate carrier from the second placement table to one of the first placement tables. When viewed in a direction perpendicular to the horizontal direction, an outer end of the second placement table in the horizontal direction is inside one of a maintenance area and a footprint area of the plurality of single-wafer type process modules as a whole, which one area is larger than the other in the horizontal direction.

### BACKGROUND OF THE INVENTION

1. Field of the Invention

The present invention relates to substrate processing apparatuses and, more particularly, to a single-wafer type substrate processing apparatus having a carry-in port through which a substrate container is carried in.

2. Description of the Related Art

In a manufacturing process of semiconductor devices or flat panels of liquid crystal display devices, a substrate processing apparatus having a processing module is used. A substrate such as a semiconductor wafer or a glass substrate is carried into the processing module in order to apply a film-forming process, such as an etching process, a chemical vapor deposition (CVD), etc., to the substrate. There is known a substrate processing apparatus referred to as a multi-chamber system, such as disclosed in Japanese Laid-Open Patent Application No. 2002-324829 (paragraphs 0013 and 0014 and FIG. 1). In this substrate processing apparatus, a plurality of single-wafer type processing modules, each of which processes wafers on an individual wafer basis, are connected to a substrate carry-in chamber set in a vacuum atmosphere or an inert gas atmosphere. The wafers are processed in series or parallel under an atmosphere isolated from an atmospheric air in order to improve a production yield and throughput.

A description will be given below of a semiconductor device manufacturing process. A plurality of types of substrate processing apparatuses, such as an existing multi-chamber system, are installed in a semiconductor manufacturing facility. Wafers are accommodated in a wafer carrier, which is an enclosure-type container for accommodating wafers, and the wafer carrier is conveyed between substrate processing apparatuses by a conveyance mechanism such as an overhead hoist transport (HOT) or an automated guided vehicle (AGV). Each substrate processing apparatus is equipped with a carry-in port through which a wafer carrier is carried. Wafers in the wafer carrier are taken out of the wafer carrier and conveyed into the interior of the substrate processing apparatus.

A plurality of carrier placement tables are arranged side by side in a conveyance arm access area of a substrate transfer chamber in the carry-in port. Because wafers have become large in size, if the access area of the conveyance arm is enlarged in left and right directions, the footprint of the substrate processing apparatus is also enlarged. As a result, a number of carrier placement tables that can be arranged in the carry-in port is limited to three at most.

The carry-in port has a role as a buffer of wafer carriers between a conveyance robot in the semiconductor manufacturing facility and the substrate processing apparatus. Additionally, when executing a so-called “dummy process” for adjusting a process condition in a process module, a dummy wafer may be carried in order to prevent the wafer placement tables in the process module from being damaged, or a storage container storing a wafer having a high priority of being processed may be carried in interruptedly. Thus, it is preferable that the carry-in port has a large capacity of storing carriers.

However, because the number of wafer carriers placed in the carry-in port is limited, there may be a case where the carry-in port is full and cannot accept any more wafer carriers, which causes a conveyance robot in the substrate transfer chamber to be set in a standby state, although the process module has a processing capacity enough to handle more wafers. Thus, there may be a problem in that a process for a wafer having a high priority is delayed, or a “dummy process” using a dummy wafer is delayed, which causes a deterioration of an operation efficiency.

On the other hand, Japanese Laid-Open Patent Application No. 2003-309158 (paragraph 0017, FIG. 2) discloses a vertical thermal processing apparatus provided with a carrier stocker above an area between a carry-in port and a substrate transfer chamber in order to convey a wafer carrier by a carrier conveyance robot between the carry-in port, the carrier stocker and a carrier placement table on a front side of the substrate transfer chamber.

However, in order to provide a carrier stocker, an installation space is needed between the carry-in port and the substrate transfer chamber, which invites an increase in the footprint of the substrate processing apparatus. Additionally, the substrate conveyance apparatus is arranged according to the conveyance path of the above-mentioned conveyance robot in order to position the placement table on the conveyance path. In a case where a carrier stocker should be added if it is necessary, the entire apparatus must be moved rearward, and pipes to the process modules and substrate transfer chamber must be rearranged. Thus, any construction to expand the apparatus must become a major project.

### SUMMARY OF THE INVENTION

It is a general object of the present invention to provide a substrate processing apparatus in which the above-mentioned problems are eliminated.

A more specific object of the present invention is to provide a substrate processing apparatus equipped with a plurality of processing modules, which can provide an installation space of a carrier in a carry-in port while preventing an increase in the footprint of the apparatus.

In order to achieve the above-mentioned objects, according to one aspect of the present invention a single-wafer type substrate processing apparatus is provided, comprising: a plurality of single-wafer type process modules for processing substrates on an individual substrate basis; a substrate transfer chamber airtightly connected to the process modules and having a substrate conveyance mechanism; a carry-in port having a plurality of first placement tables arranged in a horizontal direction so that a substrate carrier accommodating the substrates is placed on one of the first placement tables within an access area of the substrate conveyance mechanism; at least one second placement table installed on a left side or right side of an area where the first placement tables are arranged in the horizontal direction so that the substrate carrier is temporarily placed thereon; and a moving mechanism that transfers the substrate carrier placed on the second placement table to one of the first placement tables, wherein, when viewed in a direction perpendicular to the horizontal direction, an outer end of said second placement table in the horizontal direction is inside one of a maintenance area and a footprint area of the plurality of single-wafer type process modules as a whole, whichever one is larger than the other in the horizontal direction.

According to the present invention, a shortage of locations to place the substrate carrier can be compensated because the second placement table on which the substrate carrier is temporarily placed is provided in addition to the first placement tables, which are normally used when connecting the substrate carrier to the carry-in port. There is no need to move the entire substrate processing apparatus or rearrange pipes connected to the substrate processing apparatus even when adding the second placement table to the substrate processing apparatus because the second placement table is installed on a line extending horizontally leftward or rightward from the line along which the first placement tables are arranged. Additionally, the footprint of the substrate processing apparatus can be prevented from being enlarged, as compared to an original substrate processing apparatus, because the left or right outer end of the second placement table is arranged to be positioned within the footprint of the group of the process modules or the maintenance area surrounding the footprint of the process modules.

In the single-wafer type substrate processing apparatus according to the present invention, the maintenance area may be larger than the footprint area of the plurality of single-wafer type process modules as a whole. The moving mechanism may include a horizontally and vertically movable support, partly above or under the carry-in port, so that the support part holds the substrate carrier on the second placement table and transfers the substrate carrier to one of the first placement tables. Additionally, the support part of the moving mechanism may include two support members, each of which is vertically movable separate from the other.

The single-wafer type substrate processing apparatus according to the present invention may further comprise a mapping sensor configured and arranged to perform mapping of the substrates accommodated in the substrate carrier placed on the second placement table. The substrate carrier may be an enclosure-type container having a lid on a front face thereof, and an open-and-close mechanism to open and close the lid may be provided at a position facing the container placed on the second placement table.

The single-wafer type substrate processing apparatus according to the present invention may further comprise a reader configured and arranged to read carrier identification information provided to the substrate carrier placed on the second placement table.

According to another aspect of the present invention, an operation method of a single-wafer type substrate processing apparatus is provided equipped with a plurality of single-wafer type process modules and a carry-in port having a plurality of first placement tables arranged in a horizontal direction so that a substrate carrier accommodating the substrates is placed on one of the first placement tables within an access area of a substrate conveyance mechanism, the operation method comprising: placing the substrate carrier on a second placement table by a substrate carrier conveyance mechanism installed outside said substrate processing apparatus, the second placement table having an outer end in the horizontal direction located inside one of a maintenance area and a footprint area of the plurality of single-wafer type process modules as a whole, of which one is larger than the other in the horizontal direction, when viewed in a direction perpendicular to the horizontal direction; and transferring the substrate carrier from the second placement table to one of the first placement tables by a moving mechanism provided in the carry-in port.

The operation method according to the present invention may be stored in a computer readable recording medium.

Other objects, features and advantages of the present invention will become more apparent from the following detailed description when read in conjunction with the accompanying drawings.

### BRIEF DESCRIPTION OF THE DRAWINGS

FIG. 1 is a plan view of a substrate processing apparatus according to a first embodiment of the present invention;

FIG. 2 is a perspective view of a carry-in port of the substrate processing apparatus;

FIG. 3A is a plan view of a second placement table with a carrier placed thereon;

FIG. 3B is a cross-sectional view of the second placement table and the carrier shown in FIG. 3A;

FIGS. 4A, 4B and 4C are illustrations showing an operation performed in the carry-in port according to the first embodiment of the present invention;

FIG. 5 is a perspective view of a transfer mechanism according to a second embodiment of the present invention;

FIGS. 6A, 6B and 6C are illustrations showing a part of an operation performed in a carry-in port according to the second embodiment of the present invention;

FIGS. 7A, 7B and 7C are illustrations for explaining a remaining part of the operation performed in the carry-in port according to the second embodiment of the present invention;

FIG. 8 is a perspective view of a carry-in port according to a third embodiment of the present invention;

FIG. 9 is a perspective view of a transportation mechanism provided in the carry-in port shown in FIG. 8;

FIG. 10A is a plan view of first and second placement tables provided in the carry-in port shown in FIG. 8;

FIG. 10B is a perspective view of the first and second placement tables shown in FIG. 10A;

FIGS. 11A, 11B and 11C are illustrations showing a part of an operation performed in the carry-in port according to the third embodiment of the present invention; and

FIGS. 12A, 12B and 12C are illustrations showing a part of a remaining part of the operation performed in the carry-in port according to the third embodiment of the present invention.

### DETAILED DESCRIPTION OF THE PREFERRED EMBODIMENTS

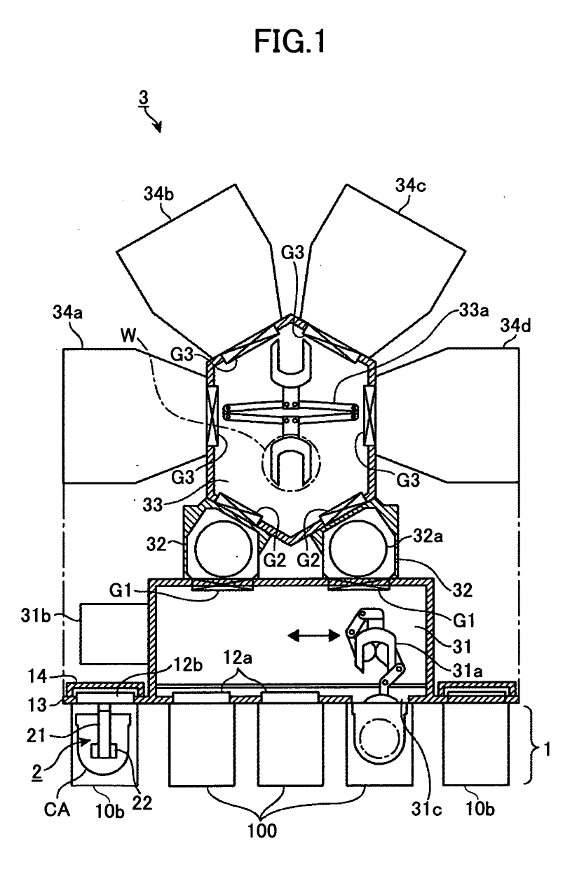

A description will now be given, with reference to FIG. 1, of a single-wafer type substrate processing apparatus (multi-chamber system) according to a first embodiment of the present invention.

The substrate processing apparatus 3 shown in FIG. 1 comprises a carry-in port 1, a first transfer chamber 31, a load-lock chamber 32, a second transfer chamber 33, and four single-wafer type process modules 34a through 34d. An enclosure type wafer carrier CA, referred to as a front-opening unified pod (FOUP), is carried into and placed in the carry-in port 1. The FOUP is a storage container for storing a predetermined number of wafers W, which are objects to be processed. The first transfer chamber 31 is provided for conveying the wafers W under an atmospheric pressure atmosphere. The atmosphere inside the load-lock chamber 32 can be switched between an atmospheric pressure and a vacuum pressure. The load-lock chamber 32 is provided with two placement tables 32a arranged on left and right sides, respectively, in order to place the wafers W in a standby state. The second transfer chamber is for conveying the wafers W under a vacuum pressure atmosphere. Each of the process modules 34a through 34d applies a process and treatment onto the wafer W carried therein on an individual wafer basis.

These equipment components are arranged in an order of the carry-in port 1, the first transfer chamber 31, the load-lock chamber 32, the second transfer chamber 33, the process modules 34a through 34d. The adjacent equipment components are airtightly connected with each other through a door 12a or gate valves G1 through G3. In the following description, the position where the carry-in port 1 is installed is assumed to be a front side of the transfer chamber 31. Additionally, the first transfer chamber 31 and the second transfer chamber 33 together constitute a substrate transfer chamber.

The carry-in port 1 comprises three first placement tables 10a linearly arranged along a front face of the first transfer chamber 31, and two second placement tables 10b, one on the left end side of the linearly arranged first placement tables 10a and the other on the right end side of the linearly arranged first placement tables 10a. The carry-in port 1 fulfills a role of receiving a wafer carrier CA, which has been conveyed by an external conveyance robot, and connecting the wafer carrier CA (hereinafter, simply referred to as carrier CA) to the substrate processing apparatus 3.

The first transfer chamber 31 includes a housing extending in left and right directions when viewed from a front side. A first conveyance mechanism 31a is installed in the first transfer chamber 31. The first conveyance mechanism 31a is rotatable, extendable and movable vertically and horizontally in order to take the wafer W out of the carrier CA and convey the wafer between the carry-in port 1 and the load-lock chamber 32. An alignment chamber 31b is provided on a side face of the first transfer chamber 31. The alignment chamber 31b is equipped with an orienter, which performs a position alignment of the wafer W.

Each of the left and right load-lock chambers 32 has the placement table 32a on which the wafer W carried into the load-lock chamber 32 is placed, and connected to a vacuum pump and a leak valve (not shown in the figure) for switching the inside atmosphere of the load-lock chamber 32 between an atmospheric pressure atmosphere and a vacuum pressure atmosphere. Additionally, the second transfer chamber 33 is formed in a hexagonal cross-sectional shape with two sides on the front side connected to the above-mentioned load-lock chamber 32 and the remaining four sides connected to the processing modules 34a through 34d, respectively. A second conveyance mechanism 33a, which is telescopic and rotatable, is installed in the second transfer chamber 33 in order to convey the wafers W between the load-lock chamber 32 and each process module 34a through 34d in a vacuum atmosphere. The second transfer chamber 33 is connected to a vacuum pump (not shown in the figure) for maintaining the vacuum atmosphere inside the second transfer chamber 33.

Each of the process modules 34a through 34d is equipped with a placement table on which the wafer W is placed and equipment components, such as a showerhead (not shown in the figure) to supply a process gas. Each of the equipment components is connected to a vacuum pump (not shown in the figure) so that a process to be performed under a vacuum atmosphere, such as, for example, an etching process using an etching gas, a film-forming process using a film-forming gas, and an ashing process using an ashing gas, can be performed. Those processes carried out in the process modules 34a through 34d may be identical processes or different processes.

In the above-mentioned structure, the wafer W stored in the carrier CA on the first placement table 10a is taken out of the wafer carrier CA by the first conveyance mechanism 31a. The wafer W is positioned in the alignment chamber 31b in the middle of conveyance in the first transfer chamber 31. Thereafter, the wafer W is transferred to one of the left and right load-lock chambers 32 and set in a standby state. After the wafer is inside, the load-lock chamber 32 is set to a vacuum atmosphere. The wafer W is taken out of the load-lock chamber 32 by the second conveyance mechanism 33a and conveyed in the second transfer chamber 32 to one of the process modules 34a through 34d, so that a predetermined process is applied to the wafer W. If different processes are applied consecutively by the process modules 34a through 34d, the wafer W is repeatedly conveyed to the second transfer chamber 33 in order to be conveyed to the process modules 34a through 34d necessary for the consecutive processes. After subjected to the necessary processes, the wafer W is conveyed through a reverse route (excluding the alignment chamber 31b), and stored in the wafer carrier CA again.

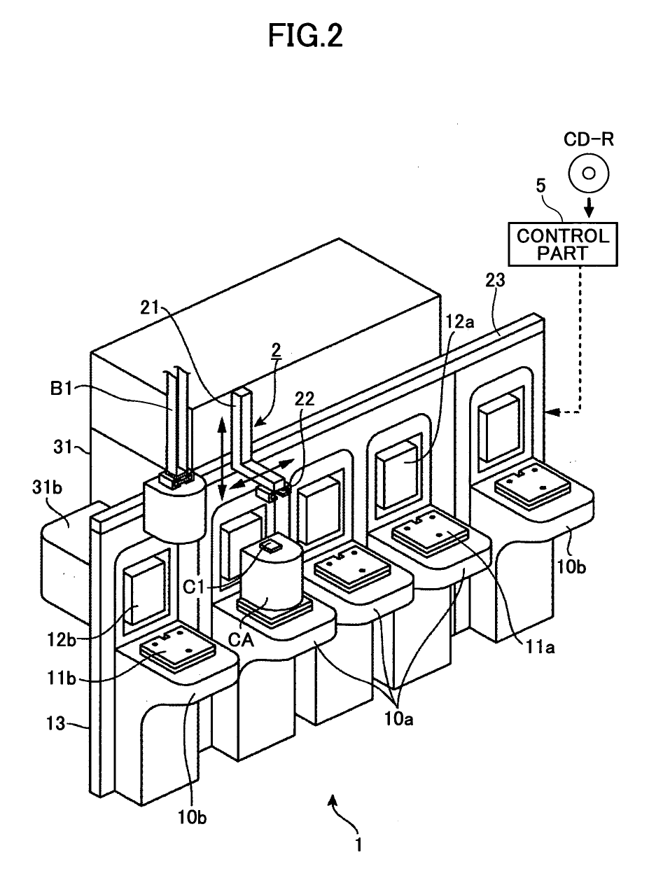

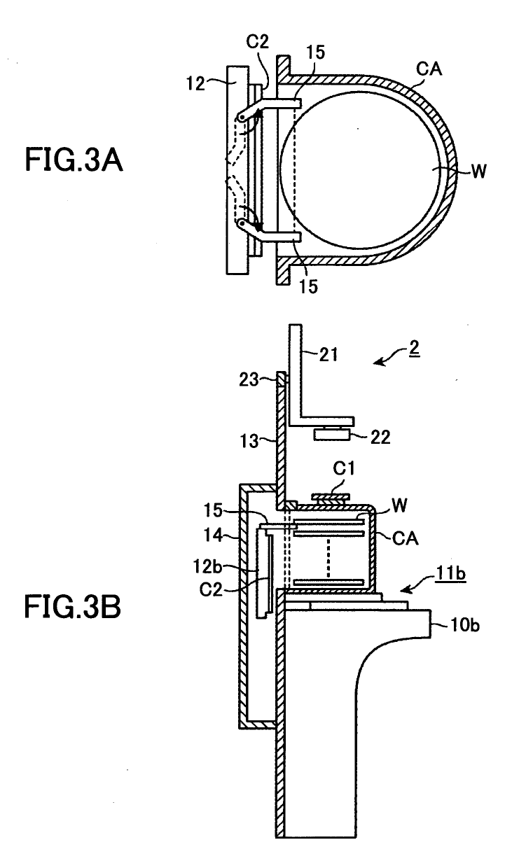

The carry-in port 1 according to the present embodiment is provided with the second placement tables 10b to compensate for the lack of locations to place the wafer carrier CA. A detailed description will now be given, with reference to FIGS. 1 through 3, of the structure of the second placement table 10b. It should be noted that the following description is based on the assumption that the second placement tables 10b are included in the carry-in port 1. FIG. 2 is a perspective view of the carry-in port 1. FIG. 3 is a cross-sectional view of the second placement table 10b viewed from above and a left side. The carry-in port 1 is equipped with the first placement tables 10a, the second placement tables 10b, and transfer mechanism 2 for transporting the wafer carrier CA from one of the second placement tables 10b to one of the first placement tables 10a. The second placement tables 10b are provided for temporarily placing the wafer carrier CA, which has been conveyed by an external conveyance robot such as an OHT.

Each of the first placement tables 10a arranged in the longitudinal direction in the front face of the first transfer chamber 31 is equipped with a tray 11a on which the wafer carrier CA is placed, as shown in FIG. 2. The tray is installed under an open-and-close door 12a. The tray 11a is configured as a double door so that the wafer carrier CA placed thereon can be pressed toward the first transfer chamber 31 by sliding an upper face side so as to connect the wafer carrier CA to the main body of the first transfer chamber 31. The open-and-close door 12A plays a role in removing a lid C2 of the wafer carrier CA connected to the first transfer chamber 31 to move the lid C2 downward. Then, as shown in the first placement table 10a on the right side of FIG. 1, an opening part 31c formed by the movement of the open-and-close door 12a is a carry-in opening through which the wafer W is carried in.

The second placement tables 10b are provided on a line extending leftward and rightward of the arrangement area of the first placement tables 10a, one on each side. The second placement tables 10b are attached to fixed walls 13 provided on left and right sides of the front part of the first transfer chamber 31, as shown in FIGS. 1 and 2. Similar to the first placement stage 10a, each second placement table 10b is equipped with a tray 11b on which the carrier CA is placed. The fixed walls 13 are attached to the front wall of the first transfer chamber 31 in order to be arranged in the same plane. Each fixed wall 13 is provided with an open-and-close door 12b having the same size as a door provided on the front wall of the first transfer chamber 31. The open-and-close door 12b is configured and arranged to be brought into engagement with a lid C2 of the wafer carrier CA by a latch mechanism (not shown in the figure). Then, the open-and-close door 12b is removed from the wafer carrier CA and temporarily moved rearward (refer to FIG. 3A), and, thereafter, the open-and-close door 12b can slide.

As shown in FIG. 3A, a mapping sensor 15 is attached to ends of two mapping-sensor arms provided on a top surface of the open-and-close door 12b. When the open-and-close door 12b removes the lid C2 from the wafer carrier CA, the mapping-sensor arms rotate as indicated by solid lines in FIG. 3A and the ends of the mapping-sensor arms move toward the wafer W accommodated in the wafer carrier CA. A transmission-type infrared sensor serving as the mapping sensor 15 is provided at the ends of the mapping-sensor arms in order to scan the interior of the wafer carrier CA downward by utilizing the downward movement of the open-and-close door 12b. While scanning, the infrared sensor (mapping sensor 15) counts a number of times when the wafers W brake into a space between the mapping-sensor arms (the mapping sensor 15) in order to acquire arrangement information of the wafers W in the wafer carrier CA (that is, existence of wafer W in each slot and the number of wafers W in the wafer carrier CA). Hereinafter, the arrangement information acquiring operation may be referred to as mapping. It should be noted that the open-and-close door 12b and a drive mechanism of the open-and-close door 12b are covered by a backside cover 14. Additionally, each open-and-close door 12a provided to the side wall of the first transfer chamber 31 is also equipped with a sensor similar to the mapping sensor 15 in order to perform mapping of the wafers W in the wafer carrier CA.

Here, the left and right ends of the second placement tables 10b, that is, the left and right outer ends of the fixed walls 13 attaching the second placement tables 10b are arranged to be inside the left and right outer ends of the process modules 34a and 34b as indicated by single-dashed chain lines in FIG. 1. The area where the second placement tables 10b are installed is a dead space in which no other substrate processing apparatuses can be installed, and, thus, the area is included in the footprint of the substrate processing apparatus 3. Accordingly, the second placement tables 10b are installed without increasing the footprint of the conventional multi-chamber system.

In other words, when viewed in a direction perpendicular to the horizontal direction, the outer ends of the second placement tables 10b in the horizontal direction are within the footprint area of the plurality of process modules 34a through 34d as a whole.

A description will be given of a transfer mechanism to transfer the wafer carrier CA located on the second placement table 10b to the first placement table 10a. As shown in FIG. 2 and FIG. 3b, the transfer mechanism 2 includes an L-shaped arm part 21, a grasping part 22 provided at the end of the arm part 21, and a moving mechanism 23 for moving the arm part 21 in a horizontal direction. The grasping part 22 is configured to hold a top flange provided on the top of the wafer carrier CA. The arm part 21 and the grasping part 22 together serve as a holding part. As shown in FIG. 2, a vertically extending portion of the L-shaped arm part 21 is movable vertically in order to vertically move the wafer carrier CA held by the grasping part 22.

The moving mechanism 23 is bridged between an upper front portion of the first transfer chamber 31 and the upper portions of the left and right fixed walls 31 so that the moving mechanism 23 does not protrude into the side of the placement stages 10a and 10b and the moving mechanism 23 does not form an obstacle in a conveyance of the wafer carrier CA by an external conveyance robot. It should be noted that a lift belt B1 shown in FIG. 2 is provided to an overhead transportation (OHT), which is not shown in the figure. The lift belt B1 and the OHT play a role to hold the top flange C1 by a grasping part provided at the end thereof and place the wafer carrier CA on the placement table 10a or 10b or carry out the wafer carrier CA. A main body of the OHT moves along a rail (not shown in the figure) provided to a ceiling part of the facility, and the OHT is arranged at a position higher than the arm part 21. Accordingly, the OHT, the OHT rail and the arm part 21 do not interfere with each other.

Additionally, as shown in FIG. 2, the carry-in port 11 is connected to the control part 5, which controls the entire substrate processing apparatus 3. The control part 5 is controlled by a computer including a central processing unit (CPU) and programs relating to various actions of the equipment components cooperating with the carry-in port 1. The programs are incorporated with a group of steps (commands) regarding controls relating to the actions of each placement table 10a or 10b and the transfer mechanism, such as an action of transferring the carrier CA from the second placement table when the wafer carrier CA is not present on the first placement table 10a. The programs are stored in a memory medium such as, for example, a hard disc, a compact disc, a magneto-optical disk, a memory card or the like, and is installed to the computer.

According to the above-mentioned structure, in the carry-in port 1 according to the present embodiment, a new wafer carrier CA, which is newly conveyed into the carry-in port 1, can be temporarily placed on the second placement table 10b even if all the first placement tables 10a are occupied by the preceding wafer carriers CA because the second placement tables 10b are installed in addition to the original first placement tables 10a. Then, after the wafers W of the preceding wafer carriers CA are completed and one of the preceding wafer carriers CA is conveyed out of the carry-in port 1, the new wafer carrier CA on the second placement table 10b is transferred to the first placement table 10a and the new wafer carrier CA is connected to the first transfer chamber 31.

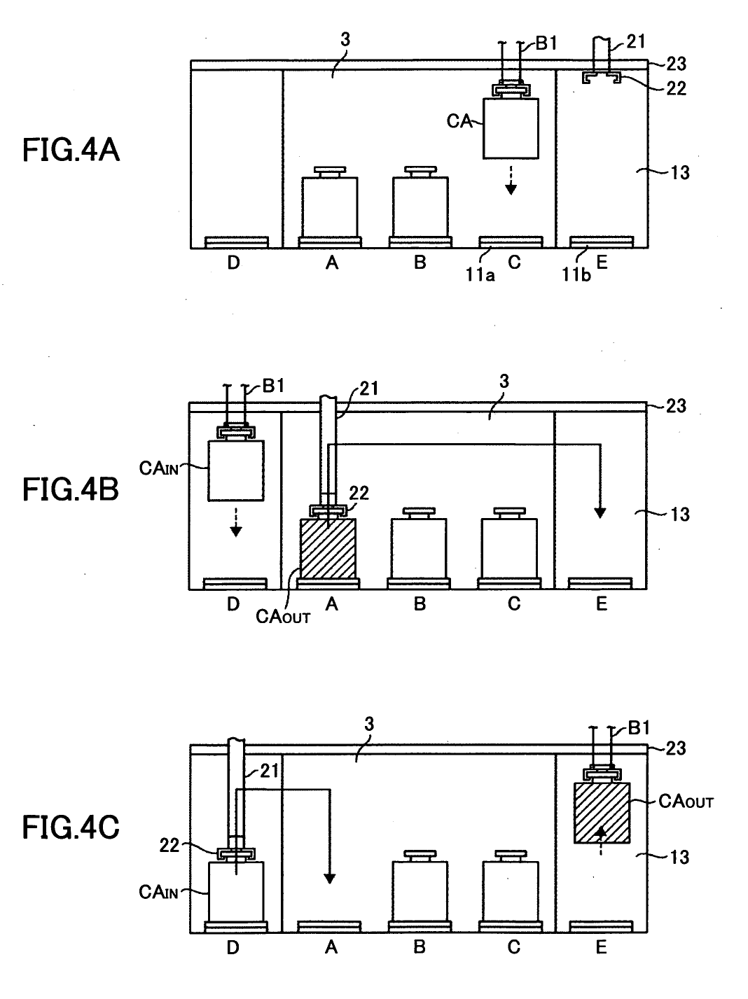

In performing the above-mentioned action, the operation in the carry-in port 1 is not limited to the above-mentioned operation, and various operations may be performed according to user's needs. A description will be given below, with reference to FIGS. 4A through 4C, of an example of operations in the carry-in port 1. In FIGS. 4A through 4C, the placement tables 10 and 10b are omitted and only the trays 11a and 11b are shown for the sake of simplification of the drawing. The first placement tables 10a are given the signs A, B and C from left in that order. The second placement table 10b on the left side is given the sign D, and on the right side is given the sign E. Additionally, the open-and-close doors 12a and 12b are also omitted.

According to the operation shown in FIGS. 4A through 4C, only the first placement tables A, B and C are used in a normal operation state as shown in FIG. 4A, and the wafer carriers CA are placed on the three placement tables and carried out by the lift belt B1 of the OHT. The mapping of the wafers W in the wafer carriers CA is carried out by the mapping sensor 15 provided to each open-and-close door 12a. During the mapping, the arm part 21 moves to a position above the second placement table E, for example, so that the arm part 21 does not disturb conveyance of the wafer carriers CA.

When a new wafer carrier CAIN is carried in as shown in FIG. 4B in a state where the first placement tables A, B and C are occupied by preceding wafer carriers CA due to a conveyance time interval of the wafer carries CA being temporarily shortened, for example, the OHT extends the lift belt B1 at a position above the second placement table D and places the wafer carrier CAIN on the second placement table D. When the carrier CAIN is placed, the tray 11b is slid as shown in FIG. 3B and the wafer carrier CA_{IN} is connected to the open-and-close door 12b. Then, the lid C2 is removed and arrangement information of the wafers W is acquired by the mapping sensor 15. Thereafter, the open-and-close door 12b is operated in a reverse direction so as to return the lid C2 to the wafer carrier CA_{IN}, and set in the standby state.

Thereafter, when the process of the wafer W in a wafer carrier CA_{OUT} on the first placement table A is completed, the arm part 21 located at a position above the second placement table E moves downward to a position close to the wafer carrier CA_{OUT}, and lifts and moves the wafer carrier CA_{OUT} to the second placement table E.

As mentioned above, when the first placement table A gets empty as shown in FIG. 4C, the arm part 21 moves to a position above the second placement table D. Then, the arm part 21 lifts and conveys the wafer carrier CA_{IN} to a position above the first placement table A, and places the wafer carrier CA_{IN} on the first placement table A. On the other hand, the wafer carrier CA_{OUT} is carried out of the second placement table E by the OHT (the lift belt B1).

The substrate processing apparatus 3 according to the present embodiment provides the following effects. A shortage of locations to place the wafer carriers CA can be compensated for because the second placement tables 10b on which the wafer carrier CA is temporarily placed, are provided in addition to the first placement tables 10a, which are normally used when connecting the wafer carriers CA to the carry-in port 1. There is no need to move the entire substrate processing apparatus 3 or to rearrange pipes connected to the substrate processing apparatus 3, even when adding the second placement table 10b to the substrate processing apparatus 3, because the second placement table 10b is installed on a line extending leftward and rightward from the line along which the first placement tables 10a are arranged. Additionally, the footprint of the substrate processing apparatus 3 can be prevented from being increased, as compared to the original substrate processing apparatus 3, because the left and right outer ends of the second placement tables 10b are arranged to be positioned inside the left and right outer ends of the group of the process modules 34a through 34d.

Although the left and right outer ends of the second placement tables 10b are arranged to be positioned inside the left and right outer ends of the group of the process modules 34a through 34d in the above-mentioned embodiment, the footprint area of the substrate processing apparatus 3 includes areas further out than the areas where the second placement tables 10b are installed with respect to the apparatus layout. The peripheral areas of the substrate processing apparatus 3, such as areas about 80 cm from the left end of the process module 34a and the right end of the process module 34d, are dead spaces. These dead spaces are referred to as maintenance areas, where other processing apparatuses cannot be installed due to being reserved as areas for a person to access the substrate processing apparatus 3 for maintenance. Thus, other second placement tables 10b may be installed on the left side and the right side of the second placement tables 10b by utilizing the dead spaces. That is, a total of four second placement tables 10b may be installed, two on the left side and two on the right side. Additionally, the processing apparatuses that do not require maintenance from the left and right directions from among the processing modules 34a through 34d may be located between the left end and the right end of the group of process modules.

It should be noted that although the second placement tables 10b are provided on each side of the area where the first placement tables 10a through 10c are installed in the present embodiment as shown in FIG. 1, the number of the second placement tables 10b is not limited to two and, for example, only one second placement table 10b may be installed on one side of the area where the first placement tables 10a through 10c are installed.

Accordingly, it is said that, at lease one second placement table 10b is installed on one side of the area where the first placement tables 10a through 10c are installed, and, when viewed in a direction perpendicular to the horizontal direction along which the first placement tables 10a through 10c are arranged, the outer end of the second placement table 10b in the horizontal direction is within one of the maintenance area and the footprint area of the plurality of process modules 34a through 34d as a whole, which one area is larger than the other area in the horizontal direction.

Further, the open-and-close door 12b for opening and closing the lid C2 of the wafer carrier CA is provided to a portion of the fixed wall 13 facing the wafer carrier CA placed on the second placement table 10b to arrange the mapping sensor 15 to acquire arrangement information of the wafers W in the wafer carrier CA in the open-and-close door 12b. Thus, the arrangement information of the wafers W can be acquired previously by utilizing the time for standing by at the position above the second placement table 10b. As a result, the wafers W can be carried out immediately after the wafers W are transferred to the first placement tables 10a. Thus, a time until the start of carrying out the wafers W can be reduced as compared to a case where the arrangement information is acquired after the wafers W are transferred to the first placement tables 10a.

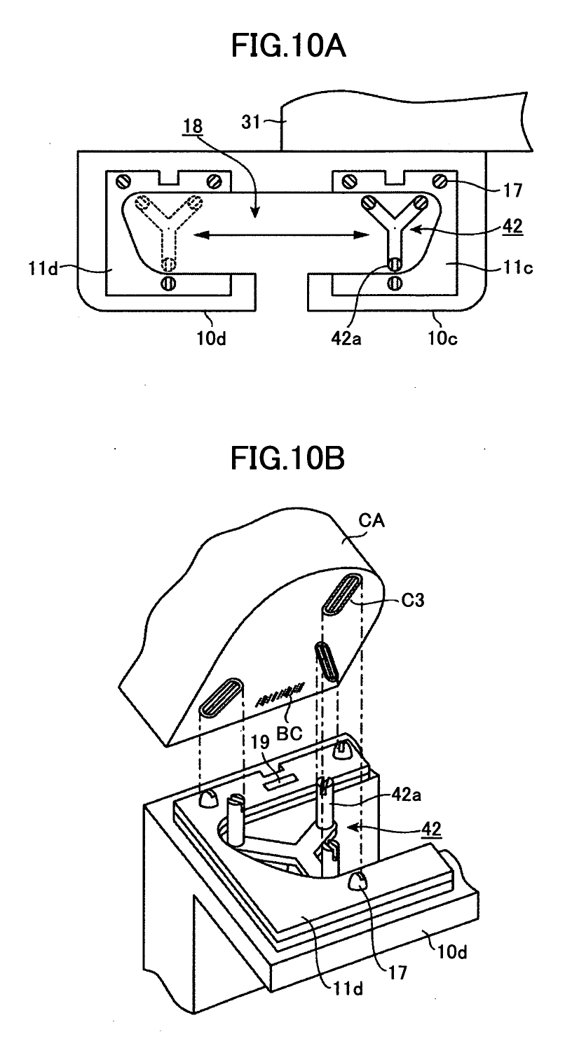

The function to be provided to the second placement table 10b is not limited to the acquisition of the arrangement information of the wafers W, and other functions may be provided to the second placement table lob. For example, there may be a case where a carrier identification (carrier ID) may be provided to a bottom surface of each wafer carrier CA, such as a bar code or a non-contact type data memory that stores information regarding the carrier ID. Normally, the information regarding the carrier ID is read by a reader attached to the first placement tables 10a. Thus, such a reader may be provided to a position at an end of the second placement table 10b in order to read the carrier ID before the wafer carrier CA is transferred to the first placement tables 10a. For example, FIG. 10 showing a third embodiment mentioned later is provided with a bar code BA on the bottom surface of a wafer carrier CA and a bar code reader for reading the bar code BA is provided at the end position of the placement table 10d.

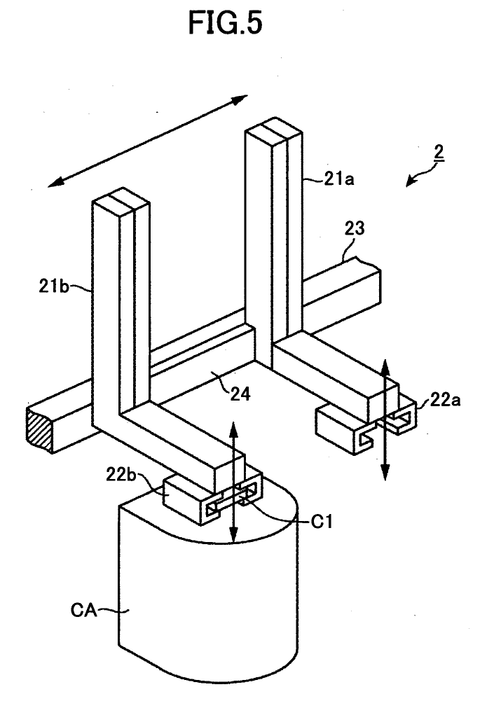

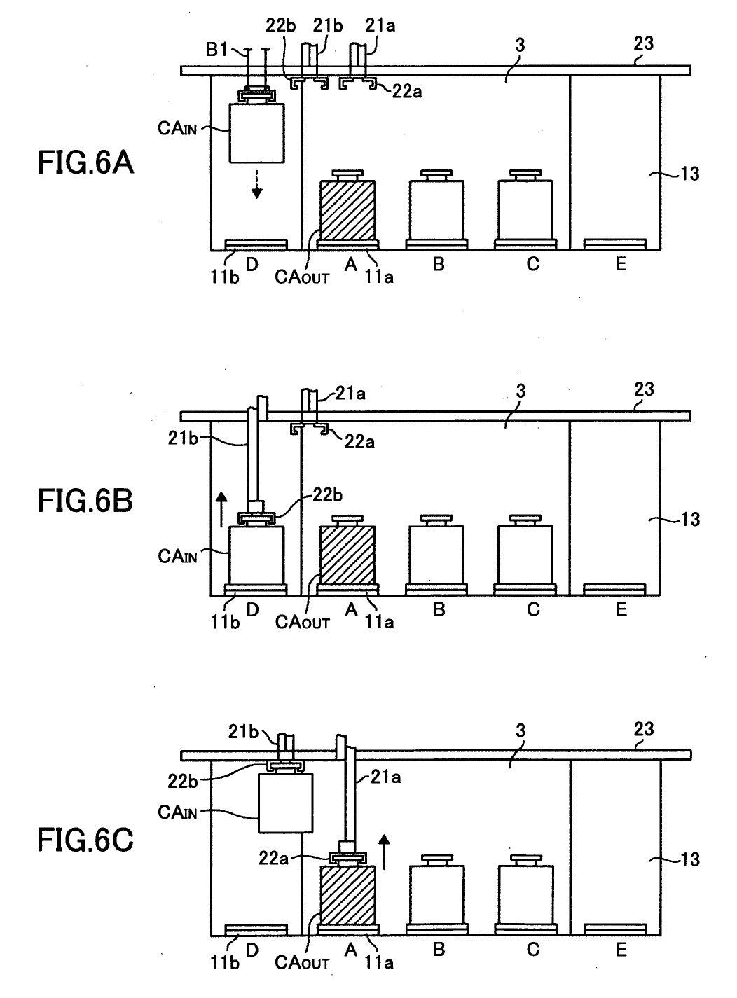

A description will now be given of a second embodiment of the present invention in which the transfer mechanism 2 is provided with two arms. FIG. 5 is a perspective view of the moving mechanism according to the second embodiment. In the second embodiment, the transfer mechanism 2 includes two arm parts or members) 21a and 21b, and grasping parts 22a and 22b are attached to the ends of the arm members 21a and 21b, respectively. The arm members 21a and 21b are connected by a connection part 24 so that the arm members 21a and 21b can move together as one piece in a horizontal direction, but move separately in a vertical direction. Additionally, in order to move the arm members 21a and 21b to a position above the second placement table 10b, the moving mechanism 23 is configured to be longer than that of the first embodiment and protrude leftward and rightward from the fixed walls 13 as shown in FIG. 6A, for example. The carry-in port 1 according to the present embodiment has the same structure as the first embodiment except for the transfer mechanism 2 having the above-mentioned structure, and descriptions thereof will be omitted.

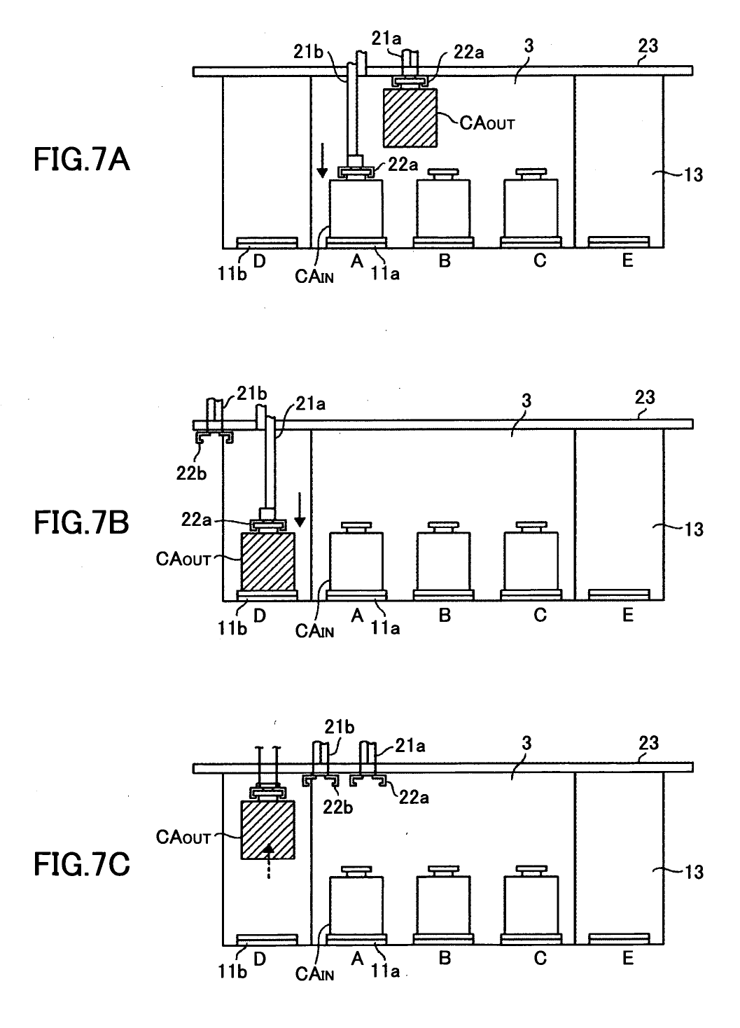

FIGS. 6A through 6C and FIGS. 7A through 7C are illustrations showing an example of an operation performed in the carry-in port 1 according to the second embodiment of the present invention. The placement tables 10a and 10b are given the same alphabets as that shown in FIGS. 4A through 4C. According to the operation shown in FIGS. 6A through 6C and FIGS. 7A through 7C, when the first placement tables A, B and C are occupied by preceding wafer carriers CA as shown in FIG. 6A, the arm parts 21a and 21b move away from the second placement table D, and a new wafer carrier CA_{IN} is placed on the second placement table D by the OHT (the lift belt B1). The lid C2 of the new wafer carrier CA_{IN} placed on the second placement table D is removed by the open-and-close door 12b and the arrangement information of the wafers W is acquired in the same manner as that explained in the first embodiment.

Thereafter, for example, when the process of the wafers W in the wafer carrier CA_{OUT} on the first placement table A is completed, the arm member 21b is moved to a position above the second placement table D and the wafer carrier CA_{IN} is lifted by the arm member 21b as shown in FIG. 6B. Then, while the arm member 21b continuously holds the wafer carrier CA_{IN}, the arm member 21a is moved to a position above the first placement table A and lifts the wafer carrier CA_{OUT} as shown in FIG. 6C.

As mentioned above, the transfer mechanism 2 moves the arm member 21b to the position above the first placement table A and places the wafer carrier CA_{IN} on the first placement table A while the arm members 21a and 21b hold the wafer carrier CA_{IN} and the wafer carrier CA_{OUT}, respectively, as shown in FIG. 7A. Thereafter, while the arm parts 21a continuously holds the wafer carrier CA_{OUT}, the arm members 21a is moved to the position above the second placement table D and places the wafer carrier CA_{OUT} on the second placement table D as shown in FIG. 7B. Finally the arm members 21a and 21b are moved away from the second placement table D and the wafer carrier CA_{OUT} is carried out by the OHT (the lift belt B1).

According to the above-mentioned second embodiment, two wafer carriers CA can be lifted simultaneously, and, thus, the two wafer carriers CA can be exchanged between one second placement table 10b and one first placement table 10a. Accordingly, there is no need to perform an operation to move the wafer carrier CA, which is to be carried out, to the empty second placement table 10b such as shown in FIG. 4B of the first embodiment. Additionally, because the moving distances of the arm members 21a and 21b are short, the wafer carrier CA can be transferred from the second placement table 10b to the first placement table 10a in a short time. It should be noted that although the arm members 21a and 21b are configured to move in a horizontal direction as one piece in the present embodiment, each of the arm members 21a and 21b may be independently moved without providing the connection part 24.

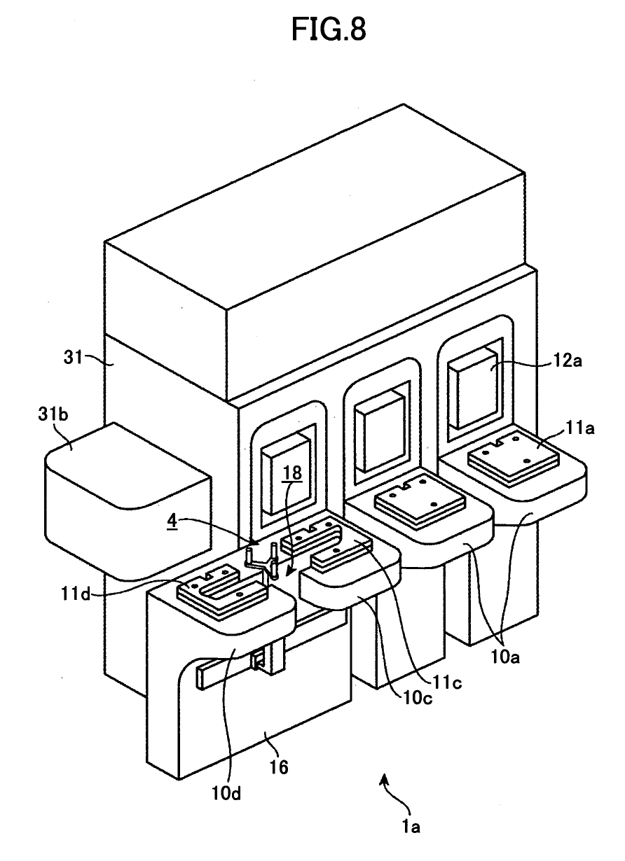

A description will now be given of a third embodiment of the present invention in which a wafer carrier CA is transferred by being held from a bottom side thereof. FIG. 8 is a perspective view of a carry-in port 1a of a substrate processing apparatus according to a third embodiment of the present invention. The substrate processing apparatus according to the third embodiment includes placement tables installed on the front side of the carry-in port 1a, the placement tables having a different structure from that of the first and second embodiments. The substrate processing apparatus also includes the first transfer chamber 31 and process modules 34a through 34d have the same structure as the first embodiment explained using FIG. 1, and, thus, descriptions thereof will be omitted.

In the third embodiment, a description will be given of a case where the second placement table 10d is provided at a position on a left-side extending line of the first placement table 10c and installed at the left end. The first placement table 10a and the second placement table 10d according to the third embodiment are formed on the same base part 16 as shown in FIG. 8. The first and second placement tables 10c and 10d are formed with a notch part 18 bridging between the placement tables 10c and 10d as shown in FIG. 10A so that a transfer mechanism 4 can be moved within the notch part 18. It should be noted the first placement tables 10a in the middle and on the right side have the same structure as that of the first embodiment.

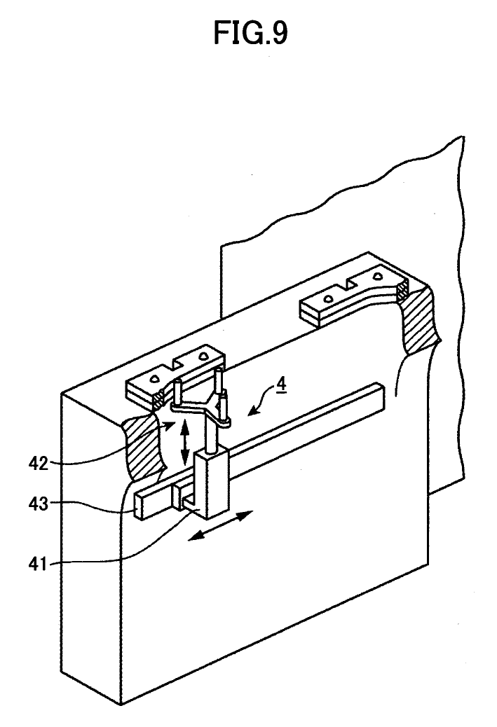

The transfer mechanism 4 includes, as shown in FIG. 9, an L-shaped arm part 41, a carrier support part 42 provided to an end of the arm part 41, and a moving mechanism 43 forming a moving path of the arm part 41. The arm part 41 and the carrier support part 42 together form a holding part. The carrier support part 42 has an upper portion extending in three directions, and a hold pin 42 having a slot formed on a top portion thereof as shown in FIG. 10B is attached to each extreme end. The carrier support part 42 is configured to telescope from the arm part 41 in order to cause the holding pins 42a to protrude or retract from the trays 11c and 11d provided on the placement tables 10c and 10d. Additionally, the arm part 41 is configured to be movable leftward and rightward by being driven by the moving mechanism 43 so that the carrier support part 42 can be moved between the placement tables 10c and 10d.

Three segments of kinematic pins 17 each having a slot on an extreme end thereof as shown in FIGS. 10A and 10B are provided to each of the trays 11c and lid of the placement table 10c and 10d. When the carrier support part 42 is moved to the first placement table 10c or the second placement table 10d, the slots of the kinematic pins 17 and the slots of the hold pins 42a are arranged in three radial directions. Thus, as shown in FIG. 10B, a kinematic coupling is formed by the kinematic pins 17 and the hold pins 42a, which are engaged with tree engagement pins C3 provided on the bottom surface of the wafer carrier CA. Thereby, the wafer carrier CA can be held at an accurate position on the placement table 10c or 10d or the carrier support part 42.

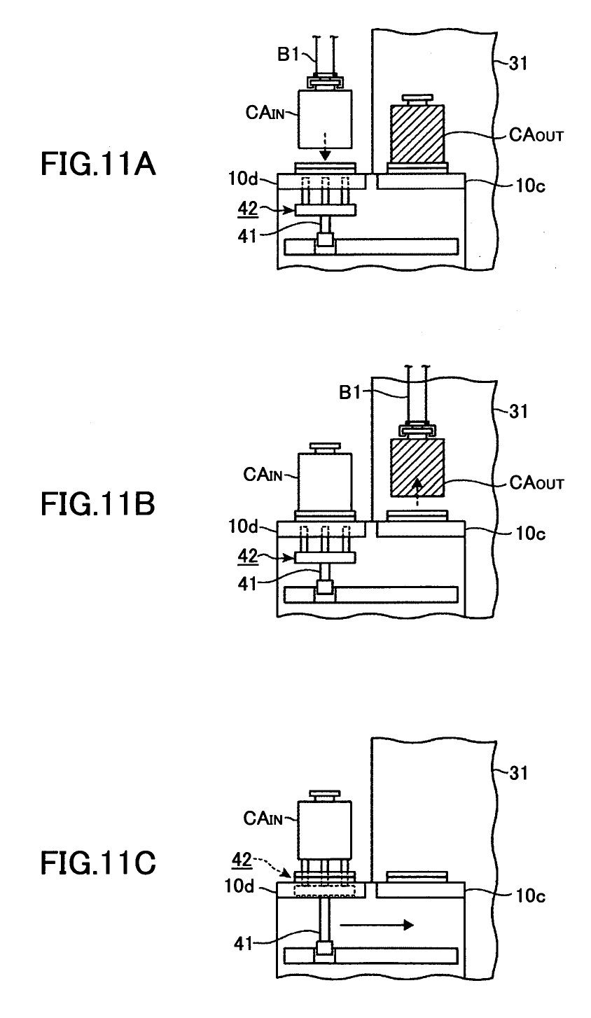

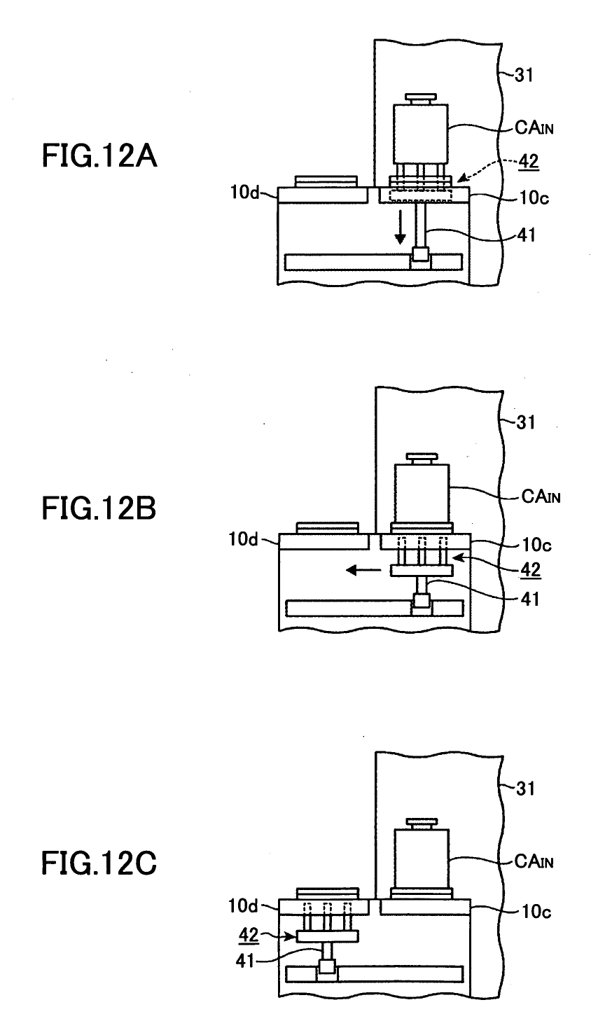

A description will be given below, with reference to FIGS. 11 and 12, of an operation performed in the carry-in port 1a according to the third embodiment. For example, when the first placement tables 10a and 10c shown in FIG. 8 are occupied, the OHT extends the lift belt B1 at the position above the second placement table 10d and places the wafer carrier CA_{IN} on the second placement table 10d as shown in FIG. 11A. After the process of the wafers W in the carrier CA_{OUT} placed on the first placement table 10c is completed, the OHT (the lift belt B1) carries the wafer carrier CA_{OUT} out of the first placement table 10c as shown in FIG. 11B.

At this time, the carrier support part 42 is set in a standby state at a position under the second placement table 10d. When the carrier CA_{OUT} is carried out, the carrier support part 42 is moved upward to lift and hold the wafer carrier CA_{IN} from the bottom side as shown in FIG. 11C. Then, the arm part 41 is moved to convey the wafer carrier CA_{IN} to a position above the first placement table 10c as shown in FIG. 12A. Thereafter, the carrier support part 42 is moved downward to place the wafer carrier CA_{IN} on the first placement table 10 as shown in FIG. 12B. Finally, the arm part 41 is moved to the second placement table 10d, and the carrier support part 42 is set in a standby state at a position under the second placement table 10d and a next wafer carrier CA is waited for.

According to the substrate processing apparatus according to the third embodiment, there is no need to perform an operation to move the transfer mechanism 4 away from the conveyance path along which the wafer carrier CA is conveyed by an external substrate conveyance robot because the transfer mechanism 4 is provided under the placement tables 10c and 10d. Additionally, the structure of the substrate processing apparatus and the control of the operation thereof can be simplified because the transfer mechanism 4 merely reciprocates the carrier support part 42 between the placement tables 10c and 10d while moving the carrier support part 42 up and down.

It should be noted that although the second placement table 10d is provided only to the first placement table 10c on the left side in the third embodiment shown in FIG. 8, another second placement table 10d may be installed symmetrically on the right side of the first placement table 10c to form another pair of the first and second placement tables 10c and 10d. Additionally, a fixed wall 13 having an open-and-close door 12b may be installed on the front face of the second placement table 10d in order to previously acquire arrangement information of wafers W.

The above-mentioned operation performed in the carry-in ports 1 and 1a can be achieved and controlled by a computer executing a program that describes the operation. Such a program may be stored in a computer readable recording medium such as a CD-ROM or the like, and is read by the control part 5 as shown in FIG. 2.

The present invention is not limited to the specifically disclosed embodiments, and variations and modifications may be made without departing the scope of the present invention.

The present application is based on Japanese priority application No. 2007-095399 filed Mar. 30, 2007, the entire contents of which are hereby incorporated herein by reference.

What is claimed is:

1. A single-wafer type substrate processing apparatus, comprising:
a plurality of single-wafer type process modules for processing substrates on an individual substrate basis;
a substrate transfer chamber airtightly connected to the process modules and having a substrate conveyance mechanism;
a carry-in port having a plurality of first placement tables arranged in a horizontal direction so that a substrate carrier accommodating the substrates is placed on one of the first placement tables within an access area of said substrate conveyance mechanism;
at least one second placement table installed on a left side or right side of an area where the first placement tables are arranged in the horizontal direction so that the substrate carrier is temporarily placed thereon; and
a moving mechanism that transfers the substrate carrier placed on the second placement table to one of said first placement tables,
wherein, when viewed in a direction perpendicular to the horizontal direction, an outer end of said second placement table in the horizontal direction is inside one of a maintenance area and a footprint area of the plurality of single-wafer type process modules as a whole, which one area is larger than the other in the horizontal direction.

2. The single-wafer type substrate processing apparatus as claimed in claim 1 wherein said maintenance area is larger than said footprint area of said plurality of single-wafer type process modules as a whole.

3. The single-wafer type substrate processing apparatus as claimed in claim 1, wherein said moving mechanism includes a horizontally and vertically movable support part above said carry-in port so that said support part holds the substrate carrier on said second placement table and transfers the substrate carrier to one of said first placement tables.

4. The single-wafer type substrate processing apparatus as claimed in claim 3, wherein said support part of said moving mechanism includes two support members each of which is vertically movable separate from the other.

5. The single-wafer type substrate processing apparatus as claimed in claim 1, wherein said moving mechanism includes a horizontally and vertically movable support part under said carry-in port so that said support part holds the substrate carrier on said second placement table and transfers the substrate carrier to one of said first placement tables.

6. The single-wafer type substrate processing apparatus as claimed in claim 1, further comprising a mapping sensor configured and arranged to perform mapping of the substrates accommodated in said substrate carrier placed on said second placement table.

7. The single-wafer type substrate processing apparatus as claimed in claim 6, wherein said substrate carrier is an enclosure-type container having a lid on a front face thereof, and an open-and-close mechanism to open and close said lid is provided at a position facing said container placed on said second placement table.

8. The single-wafer type substrate processing apparatus as claimed in claim 1, further comprising a reader configured and arranged to read carrier identification information provided to said substrate carrier placed on said second placement table.

9. An operation method of a single-wafer type substrate processing apparatus equipped with a plurality of single-wafer type process modules and a carry-in port having a plurality of first placement tables arranged in a horizontal direction so that a substrate carrier accommodating the substrates is placed on one of the first placement tables within an access area of a substrate conveyance mechanism, the operation method comprising:
placing the substrate carrier on a second placement table by a substrate carrier conveyance mechanism installed outside said substrate processing apparatus, the second placement table having an outer end in the horizontal direction located inside one of a maintenance area and a footprint area of the plurality of single-wafer type process modules as a whole, which one area is larger than the other in the horizontal direction, when viewed in a direction perpendicular to the horizontal direction; and
transferring the substrate carrier from said second placement table to one of said first placement tables by a moving mechanism provided in said carry-in port.

10. The operation method as claimed in claim 9, wherein said maintenance area is larger than said footprint area of said plurality of single-wafer type process modules as a whole.

11. The operation method as claimed in claim 9, wherein the transferring step includes holding the substrate carrier on the second placement table by a horizontally and vertically movable support part above said carry-in port.

12. The operation method as claimed in claim 9, wherein the transferring step includes holding the substrate carrier on the second placement table by a horizontally and vertically movable support part under said carry-in port.

13. The operation method as claimed in claim 9, further comprising: performing mapping on the substrates accommodated in said substrate carrier placed on said second placement table.

14. A computer readable recording medium storing a program for causing a computer to perform an operation method of a single-wafer type substrate processing apparatus equipped with a plurality of single-wafer type process modules and a carry-in port having a plurality of first placement tables arranged in a horizontal direction so that a substrate carrier accommodating the substrates is placed on one of the first placement tables within an access area of a substrate conveyance mechanism, the operation method comprising:
placing the substrate carrier on a second placement table by a substrate carrier conveyance mechanism installed outside said substrate processing apparatus, the second placement table having an outer end in the horizontal direction located inside one of a maintenance area and a footprint area of the plurality of single-wafer type process modules as a whole, which one area is larger than the other in the horizontal direction; and
transferring the substrate carrier from said second placement table to one of said first placement tables by a moving mechanism provided in said carry-in port.
